(19) United States
(12) Patent Application Publication
(10) Pub. No.: US 2025/0243565 A1
(43) Pub. Date: Jul. 31, 2025

(54) ALUMINUM ALLOY COATINGS WITH HIGH STRENGTH AND HIGH THERMAL STABILITY AND METHOD OF MAKING THE SAME

(71) Applicant: Purdue Research Foundation, West Lafayette, IN (US)

(72) Inventors: Qiang Li, Ames, IA (US); Xinghang Zhang, West Lafayette, IN (US); Yifan Zhang, Los Alamos, NM (US); Sichuang Xue, Richland, WA (US); Haiyan Wang, West Lafayette, IN (US); Nicholas Allen Richter, West Lafayette, IN (US)

(73) Assignee: Purdue Research Foundation, West Lafayette, IN (US)

(21) Appl. No.: 19/070,621

(22) Filed: Mar. 5, 2025

Related U.S. Application Data
(62) Division of application No. 17/106,964, filed on Nov. 30, 2020.
(60) Provisional application No. 62/967,923, filed on Jan. 30, 2020.

(51) Int. Cl. C22C 21/00; B82Y 30/00; C23C 14/16; C23C 14/18; C23C 14/20; C23C 14/58

(52) U.S. Cl. CPC C22C 21/00; B82Y 30/00; C23C 14/16; C23C 14/18; C23C 14/20; C23C 14/5806; C22C 2202/00

(57) ABSTRACT

A high-strength aluminum alloy coating on a metal or an alloy. The coating contains an aluminum matrix, 9R phase, fine grains in the size range of 2-100 nm, nanotwins, and at least one solute in the aluminum capable of stabilizing grains of the aluminum matrix. A method of making a high-strength aluminum alloy coating on a substrate. The method includes providing a substrate, providing at least one source for each constituent of an aluminum alloy, and depositing atoms of each constituent of the aluminum alloy from the corresponding at least one source of each constituent of the aluminum alloy on the substrate utilizing a deposition method, wherein the deposited atoms form an aluminum alloy coating containing 9R phase, fine grains, and nanotwins.

### CROSS-REFERENCE TO RELATED APPLICATIONS

The present patent application is a divisional application of U.S. patent application Ser. No. 17/106,964, filed Nov. 30, 2020, and is related to and claims the priority benefit of U.S. Provisional Patent Application Ser. No. 62/967,923 filed Jan. 30, 2020. The contents of these prior applications are incorporated in their entirety herein by reference.

### STATEMENT REGARDING GOVERNMENT FUNDING

This invention was made with government support under Contract No. DE-SC0016337 awarded by Department of Energy. The government has certain rights in the invention.

### TECHNICAL FIELD

This disclosure generally relates to methods increasing strength and thermal stability of aluminum alloy coatings and aluminum coatings having high strength and high thermal stability.

### BACKGROUND

This section introduces aspects that may help facilitate a better understanding of the disclosure. Accordingly, these statements are to be read in this light and are not to be understood as admissions about what is or is not prior art.

Age hardenable lightweight Al alloys have facilitated the development of aerospace and automotive industries and age hardening stemmed from the formation of Guinier-Preston (GP) zones in certain Al alloys, such as Al—Cu—Mg—Mn, discovered a century ago. The extension of Al alloys towards applications in harsh environment (such as high temperature and high stresses) has been often hindered in view of their inherently low strength at elevated temperatures. The low strength of conventional cast and wrought Al alloys at elevated temperature is largely ascribed to the agglomeration of solutes in forms of brittle intermetallics and significant grain coarsening. Ultrafine grained (ufg) and nanocrystalline (nc) Al alloys, enabled by severe plastic deformation, have been extensively investigated in the last two decades and the strength of ufg Al alloys can escalate to 700 MPa, and occasionally 1 GPa, in comparison to ˜600 MPa of the best commercial high strength Al alloys. However, grain growth tends to occur at low homologous temperature (<0.45 Tₘ) in ufg or nc Al alloys due to the excess energy stored at grain boundaries (GBs).

Grain refinement is an effective to enhance the mechanical strength of metallic materials. Experimental and computational evidences have often shown the existence of a “strongest grain size” for various face-centered-cubic (fcc) metals with various stacking fault energies (SFEs). But nanograins are prone to rapid grain growth even at room or modest temperatures or under stress. Prior studies show that nanograins can be stabilized via alloying strategy, although the retention of fine grain size in response to elevated temperature or high stress remains a challenge. In general, alloying can kinetically stabilize nc metals against GB motion through Zener drag from additional solutes or nanoprecipitate-induced Zener pinning, or thermodynamically reduce GB energy via solute segregation at GBs instead of forming intermetallics.

Recently, there are increasing studies on solid solution strengthening in binary Al alloys, using solutes such as Ag, Ti, Cr, Mg, Mo and W. Some of these studies show that certain transition metal solutes, such as Fe, Co and Ni, can introduce nanograins and fine twins into sputtered Al alloys with high SFEs and lead to ultra-high flow stress, ˜1.5 GPa. However, these binary Al alloys still have limited thermal stabilities, determined by the intermetallic formation energy, decomposition temperature of solid solution etc. For instance, the recrystallization temperature in nanotwinned (nt) Al—Fe solid solution alloys is 250-280° C., when Fe solutes agglomerate into intermetallic phase, depriving the solutes necessary for Zener drag effect. These ufg Al—Fe alloys have better thermal stability comparing with most of conventional coarse grained (cg) and ufg Al alloys. However, these nt Al—Fe alloys have low mechanical strength, ˜130 MPa, when tested at 300° C., limiting their potential applications in harsh high-temperature harsh environments, such as recipe development in powder sintering, micro- and nanoelectromechanical systems, thermal transport, wear resistance, engine and combustion coating at elevated temperatures, just to name a few.

Thus there exists an unmet need for alloy materials satiable for use as coatings with high mechanical strength and high thermal stability.

### SUMMARY

A high-strength aluminum alloy coating on a metal or an alloy is disclosed. The coating contains an aluminum matrix, 9R phase, fine grains fine grains in the size range of 2-100 nm, nanotwins, and at least one solute in the aluminum capable of stabilizing grains of the aluminum matrix.

A method of making a high-strength aluminum alloy coating on a substrate is disclosed. The method includes providing a substrate, providing at least one source for each constituent of an aluminum alloy, and depositing atoms of each constituent of the aluminum alloy from the corresponding at least one source of each constituent of the aluminum alloy on the substrate utilizing a deposition method, wherein the deposited atoms form an aluminum alloy coating containing 9R phase, fine grains, and nanotwins.

### BRIEF DESCRIPTION OF DRAWINGS

Some of the figures shown herein may include dimensions. Further, some of the figures shown herein may have been created from scaled drawings or from photographs that are scalable. It is understood that such dimensions or the relative scaling within a figure are by way of example, and not to be construed as limiting. Further, in this disclosure, the figures shown for illustrative purposes are not to scale and those skilled in the art can readily recognize the relative dimensions of the different segments of the figures depending on how the principles of the disclosure are used in practical applications.

FIGS. 1A and 1B show cross-section bright-field TEM micrographs of nt Al—Fe—Ti with a composition of Al_{89.8}Fe_{5.5}Ti_{4.7} at low and intermediate magnifications, respectively, with an SEAD inset identifying a columnar structure.

FIGS. 1C and 1D show a dark-field TEM micrograph and SAED pattern, respectively, showing a highly (111)-textured Al—Fe—Ti alloy with high density twins.

FIG. 1E shows an intermediate magnification TEM micrograph showing ITBs with 9R. Columnar structure is further divided by excess low angle grain boundaries (LAGBs) indicated by three fast Fourier transform (FTT) patterns.

FIG. 1F shows an TEM micrograph highlighting a diffuse ITB, i.e. 9R phase.

FIG. 1G shows an TEM micrograph highlighting a LAGB.

FIG. 2A shows XRD profiles of Al_{89.8}Fe_{5.5}Ti_{4.7} (hereafter abbreviated as Al—Fe—Ti) annealed up to 500° C., showing (111) out-of-plane texture and the presence of extra phases as the temperature reaches or exceeds 400° C.

FIG. 2B shows magnified XRD profiles corresponding to those in FIG. 2A indicating peak shift and the formations of Al₆Fe and Al₃Ti phases.

FIGS. 3A, 3B, 3C and 3D show EDS compositional maps and corresponding line profiles directly below each compositional map on cross-section TEM (XTEM) specimens of Al—Fe—Ti annealed at 350° C., 400° C., 430° C., and 500° C., respectively.

FIGS. 4A, 4B, 4C and 4D show phase mapping on (XTEM) specimens of Al—Fe—Ti annealed at 350° C., 400° C., 430° C. and 500° C., respectively.

FIGS. 5A1, 5A2, and 5A3 show XTEM micrographs revealing stable columnar nanograins and twins up to 350° C. compared to the as-deposited reference. Twin boundaries, 9R and low angle grain boundaries (LAGBs) are shown. These micrographs show that fcc phase solely exists.

FIGS. 5B1, 5B2, and 5B3 show XTEM micrographs indicating that specimens annealed at 400° C. still possess nanocolumns and nanotwins. These micrographs show that the alloy mostly is constructed by fcc phase but Fe-rich GB regimes in few nanometer thick resemble orthorhombic Al₆Fe phase.

FIGS. 5C1, 5C2 and 5C3 show XTEM micrographs revealing the onset of recrystallization and precipitation at 430° C. These micrographs show that nanoscale orthorhombic Al₆Fe phase and particulate shaped L12 cubic Al₃Ti coexist.

FIGS. 5 D1-D3 show XTEM micrographs displaying a multi-phase microstructure after recrystallization at 500° C. TEM micrographs show a nanocomposite containing fcc Al, orthorhombic Al₆Fe and tetragonal D0₂₂ Al₃Ti.

FIG. 6A shows hardness measurements by nanoindentation, demonstrating that Al_{95.3}Fe_{2.8}Ti_{1.9} exhibits precipitous softening at around 330° C. and Al_{89.8}Fe_{5.5}Ti_{4.7} softens prominently after annealing beyond 400° C. Softening in binary Al—Fe with comparable Fe contents took place after annealing at 250-280° C.

FIG. 6B shows the evolution of grain sizes of fcc Al and intermetallic Al₆Fe and Al₃Ti phases as a function of annealing temperature. Binary nt Al—Fe and ufg pure Al are cited for comparison.

FIGS. 7A, 7C, 7E and 7G show room temperature in-situ micropillar compressions and the corresponding engineering stress-strain curves of as deposited Al—Fe—Ti specimens and specimens annealed at 300° C., 400° C. and 500°, respectively.

FIGS. 7B, 7D, 7F and 7H show the corresponding SEM snapshots at different strain levels upon deformation of as deposited Al—Fe—Ti specimens and specimens annealed at 300° C., 400° C. and 500°, respectively.

FIGS. 8A, 8C, 8E and 8G show elevated temperature in-situ micropillar compressions and the corresponding engineering stress-strain curves of as deposited Al—Fe—Ti specimens tested at 100° C., 200° C., 300° C. and 400°, respectively.

FIGS. 8B, 8D, 8F and 8H show SEM snapshots at different strain levels upon deformation of Al—Fe—Ti specimens tested at 100° C., 200° C., 300° C. and 400° C., respectively.

FIG. 9 shows schematic representations of microstructures showing that both nt binary and ternary Al alloys prevailing upon heat treatment and illustrating superb thermal stability of nt Al—Fe—Ti alloys. Sections marked a and b show that binary Al—Fe with solute supersaturation and columnar nanograins coarsens as 280° C.≤Tₐ≤300° C. upon Al₆Fe formation. Sections marked c and d show that, in comparison with Al—Fe, Fe segregation at GBs as a consequence of Ti solute pinning and lowered GB energy occurs at 300° C.≤Tₐ≤400° C.; Sections marked e and f show that the Al Fe swiftly flourishes the moment that Ti starts to segregate (Tₐ=430° C.) and eventually ternary alloys fully recrystallize (Tₐ=500° C.)

FIG. 10A shows the flow stress (at 7% strain, or converted from nanoindentation hardness divided by a Tabor factor of 2.7) of Al—Fe—Ti as a function of annealing temperature, displaying that the nt Al—Fe—Ti alloys remain high strength up to 400° C., 0.72 Tₘ of Al, in comparison with prior studies on ufg, nc and nt Al and/or Al alloys

FIG. 10B shows the flow stress at 7% strain for Al—Fe—Ti stay as high as 1.7 GPa at 300° C., making it one of the strongest nanostructured Al alloys tested at a similar temperature range.

FIG. 10C shows the normalized shear stress (t/u) as a function of homologous temperature (Tₐ/Tₘ) for nt Al—Fe—Ti in comparison with other fcc-based (Ni— and Cu—) nc and nt alloys. Tₜₑₛₜ and Tₘ denotes testing and melting temperature, respectively.

FIG. 11 shows the hardness of Al-4.5 Ni and Al-4.5Ni-3Ti alloys annealed at different temperatures.

FIG. 12A shows an XTEM micrograph showing recrystallized nanograins in Al-4.5Ni annealed at 150° C. for 1.5 hours.

FIG. 12B shows TEM micrograph revealing Al₃Ni intermetallics within nanograins.

FIG. 12C shows TEM image displaying scattered residual 9R phase.

FIG. 12D shows EDS map exhibiting Ni solute segregation in the annealed Al-4.5 Ni.

FIGS. 12E and 12F show bright-field and dark-feld XTEM images respectively of nanotwinned columnar grains in Al-4.5Ni-3Ti alloy annealed at 250° C. for 1.5 hours.

FIG. 12G shows TEM image of high-density 9R phase in nanoscale columnar grains.

FIG. 12H shows EDS map revealing the absence of Ni and Ti solute segregation in the annealed Al-4.5Ni-3Ti alloy.

FIG. 13A shows formation energy of Fe—Ti, Fe—Fe and Ti—Ti solute pairs at various substitutional sites in Al matrix, indicating that Ti addition to Al—Fe solid solution alloys could stabilize Fe occupancy of substitutional sites in bulk Al solvent.

FIG. 13B shows the comparable energies, i.e. 2×E_{Fe—Ti}−E_{Fe—Fe}−E_{Ti—Ti}, of Fe—Ti pairs with 25 feasible configurations near ITBs.

FIGS. 13C and 13D show the lowest and second lowest energy configurations respectively of Fe and Ti positioned in vicinity of ITBs, indicative of favored solute configurations wherein Fe segregate at ITBs with surrounding Ti solutes. Fe solutes are positioned at core sites of ITBs with adjacent Ti solutes. The DFT calculations are detailed in supplementary session.

### DETAILED DESCRIPTION

For the purposes of promoting an understanding of the principles of the disclosure, reference will now be made to the embodiments illustrated in the figures and specific language will be used to describe the same. It will nevertheless be understood that no limitation of the scope of the disclosure is thereby intended, such alterations and further modifications in the principles of the disclosure, and such further applications of the principles of the disclosure as illustrated therein being contemplated as would normally occur to one skilled in the art to which the disclosure relates.

In this disclosure, we disclose that nt Al—Fe—Ti solid solution alloy coatings of this disclosure exhibit superb thermal stability up to 400° C., 0.72 of the melting temperature of Al. In-situ micropillar compression experiments show that the nt Al—Fe—Ti alloys can preserve an exceptionally high flow stress of ˜2.2 GPa at an annealing temperature of 400° C. Furthermore, the alloy retains a high flow stress of ˜1.7 GPa when tested at 300° C., making it one of the strongest high temperature Al alloys reported to date. The synergistic effect of Fe and Ti solutes on achieving high strength and thermal stability is discussed.

The experimental methods used in experiments leading to this disclosure are described below.

Specimen preparation: An AJA ATC-2200-UHV system with a base pressure of 3×10⁻⁹ Torr was used to co-sputter Al (99.999%), Fe (99.98%) and Ti (99.99%) onto HF-etched Si (111) wafers adhered to the rotary counter electrode at an Ar pressure of 2 mtorr. The deposition rates for Al, Fe and Ti were calibrated according to the measurements from a built-in quartz crystal rate monitor in order to control the compositions of ternary alloys which will be the coating on substrate which on this case is HF-etched Si (111) wafer. Some specimens were heat treated at 100-500° C. for 1 h with a ramping rate of 20° C./min in a vacuum furnace evacuated to 10⁻⁷ Torr. To control the compositions of the ternary alloy coatings, the deposition power for each of the guns with the sources for the constituents of the alloys were tailored. The deposition powers vary from 40 W to 300 W.

Micropillars for in-situ mechanical testing were made by focused ion beam (FIB) technique using an FEI Helios Nanolab™ 600i Dual beam FIB/SEM. A series of concentric annular trench milling and surface polishing using progressively decreasing currents had been applied to fabricate micropillars with a diameter of ˜1 μm and a diameter-to-height aspect ratio of 1:2 with a tapering angle of ˜2-3° through this work. The FIB conditions were carefully selected to prevent the FIB milling of substrates.

Mechanical testing: The in-situ micromechanical experiments were performed on a Hysitron PI 88 PicoIndenter inside the FEI quanta 3D FEG SEM microscope to simultaneously monitor the load-displacement response and geometric deformation. A 10 μm tungsten carbide (WC) flat punch indenter was adhered to a high-load load cell containing a capacitive transducer and a piezoelectric actuator for uniaxially compressing micropillars at room and elevated temperatures. To adjust axial alignment between indenter and micropillar, five-degree of freedom motions offered by sample stage, X, Y, Z, tilt and rotation, were constantly adjusted prior to compressions. In particular, for experiments conducted at elevated temperature up to 400° C., in-situ setup was adapted by adding a probe heater, a stage heater and water-cooling pipes onto two terminals. Temperature rose simultaneously on two sides at a rate of 10° C./min and stayed isothermally at a designated temperature for a minimum of 0.5 h prior to conducting experiments to remove thermal drift from temperature discrepancy between the specimen and indenter. A constant strain rate of 5×10⁻³/s was used in a displacement mode and two partial unloading segments were intentionally incorporated into load function to verify alignment condition. A preloading at 50 μN for 45 s was applied to compensate drift-related displacement error. The mean force and displacement fluctuation were measured at ±5 μN and ±0.6 nm, respectively

To compensate the displacement from machine compliance and the WC indenter, the pressed elastic half-space was considered to obtain the valid displacement, u, using Sneddon equation as:

$$u = {u}_{mea .} - \frac{1 - {v}_{WC}^{2}}{{E}_{WC}} ( \frac{F}{{d}_{t}} ) - \frac{1 - {v}_{Si}^{2}}{{E}_{Si}} ( \frac{F}{{d}_{b}} )$$

where uₘₑₐ. and F represent the measured displacement and load, respectively. E and v are the Young's modulus and Poisson's ratio, respectively. dₜ and d_{b} are the top diameter and the base diameter of the micropillars. The diameter at the middle height of micropillars has been chosen for calculation of the flow stress.

Ex-situ nanoindentation hardness of the Al—Fe—Ti alloys was carried out on a Hysitron TI premier using a diamond Berkovich indenter with a validated area function. At least 20 indents were conducted at each contact depth. The maximum indentation depth is approximately 15% of the film thickness to avoid influence from substrate.

Materials characterizations: TEM, STEM imaging and energy-dispersive X-ray spectroscopy (EDS) mapping were carried out on an FEI Talos 200X microscope operated at 200 kV with Fischione ultrahigh resolution high-angle annular dark field (HAADF) detectors and super X EDS with four silicon drift detectors. X-ray diffraction (XRD) was acquired using a Panalytical Empyrean X′pert PRO MRD diffractometer with a 2×Ge (220) hybrid monochromator to select Cu Kal line. Both plan-view and cross-section TEM specimens were prepared by mechanical grinding and dimpling, followed by low-energy Ar-ion milling inside a Gatan precision ion polishing system. Crystallographic orientation and phase analyses were performed using a NanoMEGAS ASTAR™ system with a precession angle of 0.6°, a camera length of 260 mm and a step size of 4 nm through this study. Index reliability of 10 was used for phase identification and 30-40 index reliability was typically obtained for each phase.

Results of the experiments conducted are described below.

Microstructural evolution after annealing: Two types of ternary alloys were selected in this study, Al_{89.8}Fe_{5.5}Ti_{4.7}, and Al_{95.3}Fe_{2.8}Ti_{1.9} (all compositions are in atomic percentage through this study). Our prior study shows that 5.5 at. % Fe leads to optimum thermal stability in nt binary Al—Fe solid solution alloys. Meanwhile, Al_{94.5}Fe_{5.5} and Al₉₇Fe₃ binary alloys were used as a reference. As the story will focus primarily on the Al_{89.8}Fe_{5.5}Ti_{4.7} alloy, for simplicity we refer this composition to Al—Fe—Ti alloy unless it is necessary to specify the composition for the alloys.

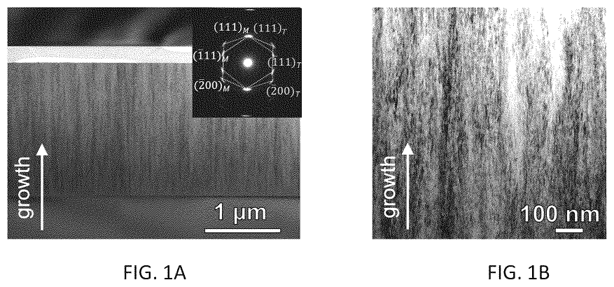

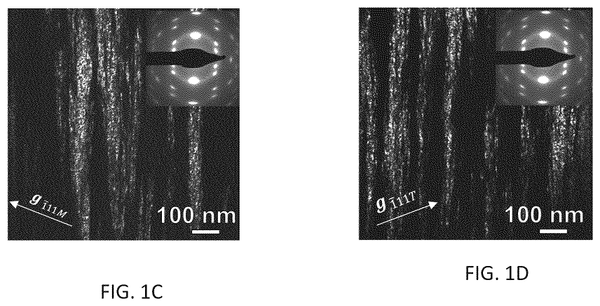

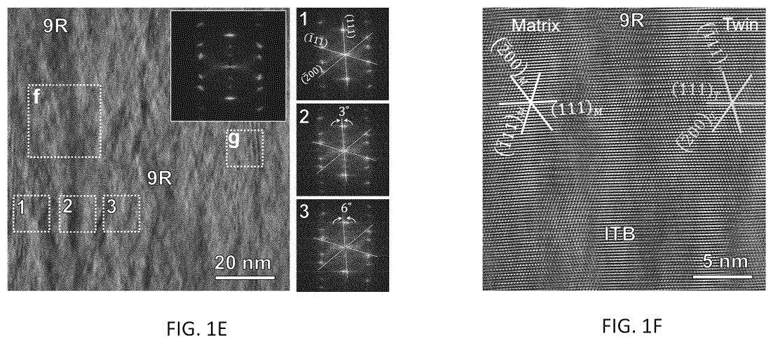

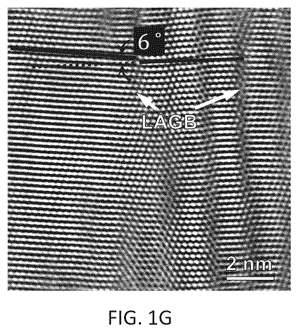

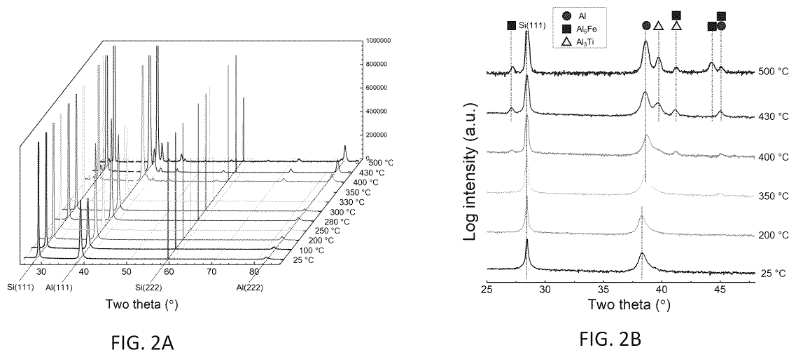

Cross-section TEM (XTEM) micrographs in FIGS. 1A and 1B reveal that the Al—Fe—Ti alloy contains columnar nanograins with abundant incoherent twin boundaries (ITBs), similar to the microstructure of binary Al_{94.5}Fe_{5.5}, which is supported by the selected area electron diffraction pattern (SAED). FIGS. 1C and 1D show a dark-field TEM micrograph and SAED pattern, respectively, showing a highly (111)-textured Al—Fe—Ti alloy with high density twins. FIG. 1E shows an intermediate magnification TEM micrograph showing ITBs with 9R. Columnar structure is further divided by excess low angle grain boundaries (LAGBs) indicated by three fast Fourier transform (FTT) patterns. FIG. 1F shows a TEM micrograph highlighting a diffuse ITB, i.e. 9R phase. High resolution TEM is abbreviated as HRTEM. FIG. 1G shows an TEM micrograph highlighting a LAGB. The average twin spacing for the Al—Fe—Ti is 23±8 nm and the interiors of the columnar nanograins has high-density low angle GBs (LAGBs) as shown in FIGS. 1E through 1G, with an average grain size of 5±2 nm. Moreover, Fe and Ti are homogenously dispersed in as-deposited ternary Al alloy, as shown in FIGS. 2A and 2B. The formations of 9R phase and nanotwin structure are highly technique- and composition-dependent. The high quenching rate of the sputtering technique rendered a supersaturated solid solution in the ternary alloys and the pinning effects of solutes and coating texture effect gave rise to high density ITBs with 9R phase.

To probe structural stability, the XRD measurements have been performed on as-deposited Al—Fe—Ti and specimens annealed at various temperatures up to 500° C. (FIG. 2A). The single fcc phase remains upon annealing prior to 400° C., when the formation of intermetallic phases emerges as shown in the magnified profiles (FIG. 2B). New reflections are affiliated with Fe-rich and Al₃Ti intermetallic, but the legit identification of phases call for further analysis because of possible peak overlapping between Al₆Fe with orthorhombic structure and Al₁₃Fe₄ with monoclinic C12/ml structure and among polymorphic Al₃Ti with transformation of L1₂, D0₂₃ and D0₂₂ phase. Also, the (111) texture remains dominant up to 500° C. despite small peak shift.

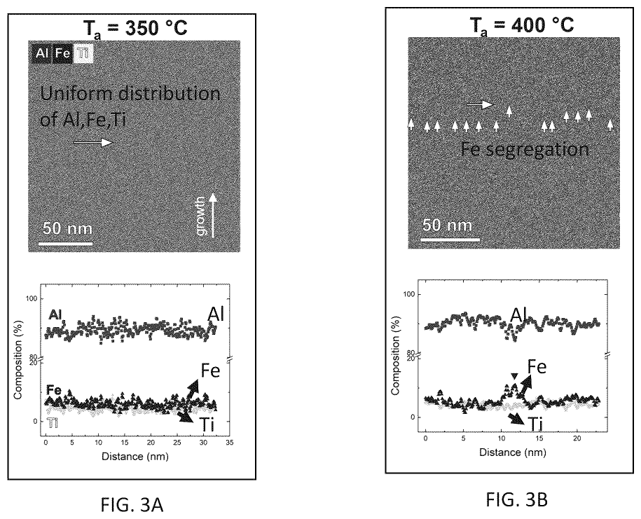

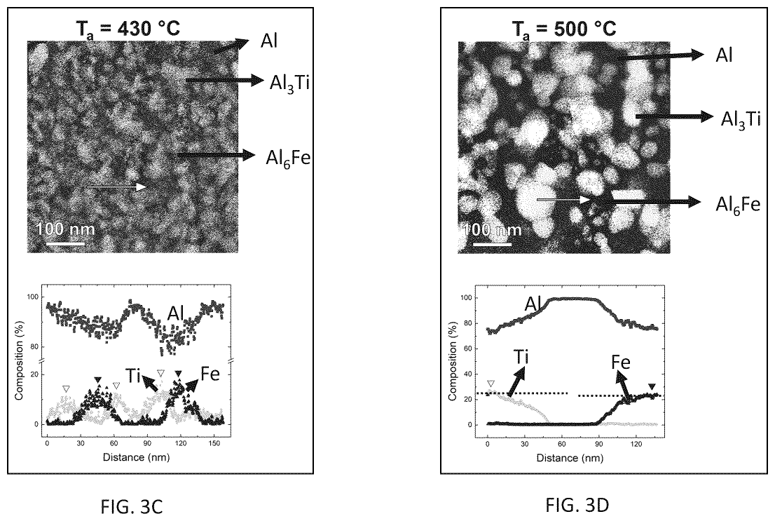

Cross-section STEM-EDS mapping was employed to examine the Fe and Ti distributions upon heating. Nt Al—Fe—Ti annealed at 350° C. has not undergone noticeable chemical segregation (FIG. 3A). After annealing at 400° C., Fe segregation up to 10% is observed along columnar grain boundaries (indicated by white arrows), yet Ti remains homogeneously dispersed (FIG. 3B). At 430° C., both Fe and Ti segregate into nanoscale agglomerations as shown in FIG. 3C, a signature for the structural coarsening. Fe and Ti appear to segregate alternatively orthogonal to the growth direction, with 13% Fe and 8.5% Ti in the segregates. Complete recrystallization occurs at 500° C., leading to the formation of equiaxed grains (FIG. 3D).

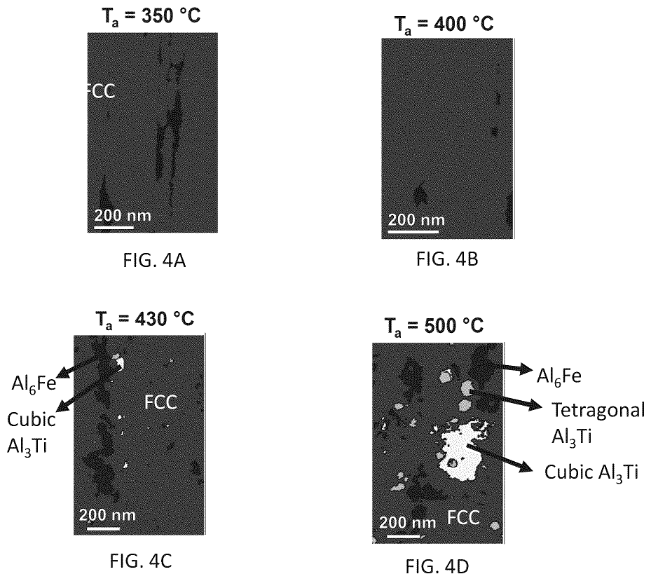

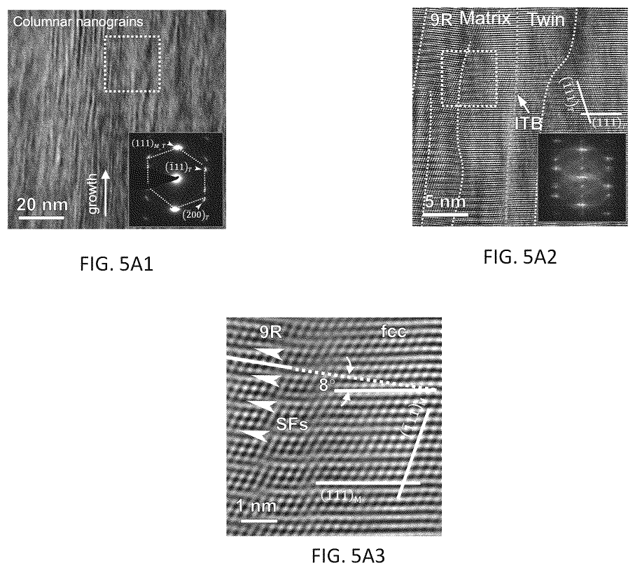

ASTAR phase mapping experiments were conducted on the XTEM specimen with five simulated diffraction banks, including fcc Al, cubic L1₂ Al₃Ti, tetragonal D0₂₂ Al₃Ti, orthorhombic cmcm Al₆Fe and monoclinic C12/ml Al₁₃Fe₄. As shown in FIGS. 4A and 4B, after heat treatment at 350 and 400° C., the alloys mostly remained fcc phase. At 430° C., FIG. 4C shows the formation of Al₆Fe, with little indication of Al₃Ti intermetallics. Al₆Fe phase is vaguely vertically aligned. At 500° C., equiaxed multiphase nanocomposite containing fcc Al, Al₆Fe and two types of Al₃Ti form as shown in FIG. 4D. It is worth noting that most of Al₃Ti nanoprecipitates remain structurally intact, whereas Al₆Fe agglomerations are comprised of multiple sub-grains. In addition, no equilibrium Al₁₃Fe₄ phase has been identified. And the Al₆Fe precipitates have orthorhombic structure, but with ˜20% Fe more than the stoichiometry of Al₆Fe.

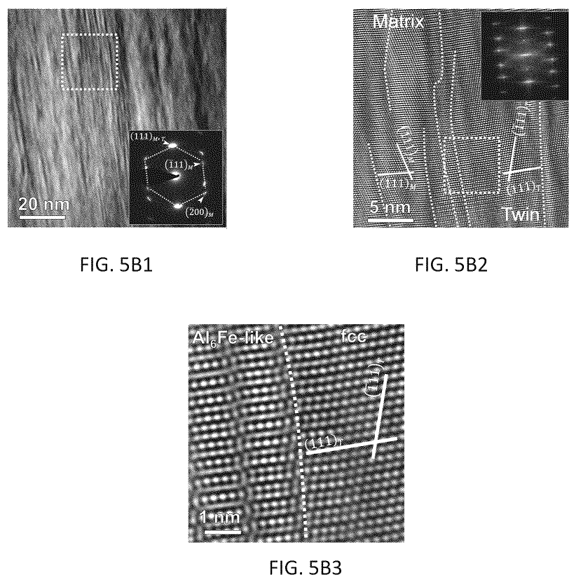

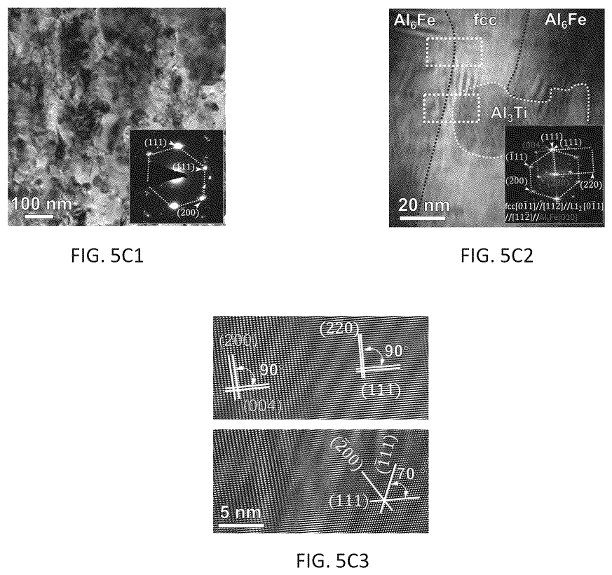

To examine structural stability in detail, XTEM analyses have been performed. The columnar nanograins with nanotwins and 9R phase (or diffused ITBs) retained after annealing at 350° C. as shown in FIGS. 5A1, 5A2, and 5A3. Upon annealing at 400° C., 0.72 of melting temperature (Tₘ) of Al, TEM and TEM analyses in FIGS. 5B1, 5B2 and 5B3 indicate the diminishing ITBs, and the formation of the precursor of Al₆Fe phase. In contrast, annealing at 430° C. gave rise to nanoprecipitates containing Al₆Fe phase and L1₂ Al₃Ti particulate (FIGS. 4C1. 4C2 and 4C3). The nanoprecipitates in FIG. 5C2 shows the orientation relation of fcc Al[112̅]//Al₃Ti L1₂ [01̅1]//Al₆Fe [010], in good agreement with ACO mapping results. Equiaxed multiphase nanocomposite formed at 500° C., locally containing fcc Al, D0₂₂ Al₃Ti, and Al₆Fe phase, with the local orientation relation of fcc Al[01̅1]//Al₃Ti D0₂₂ [1̅31̅]//Al₆Fe [001̅] as shown in FIG. 5D2. The three-phase zone is magnified in FIG. 5D3 where fcc is under strained condition and has slightly different inclined interplanar angles.

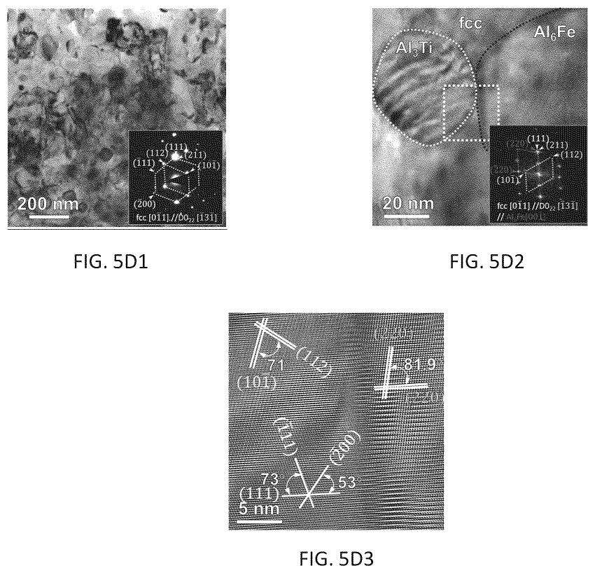

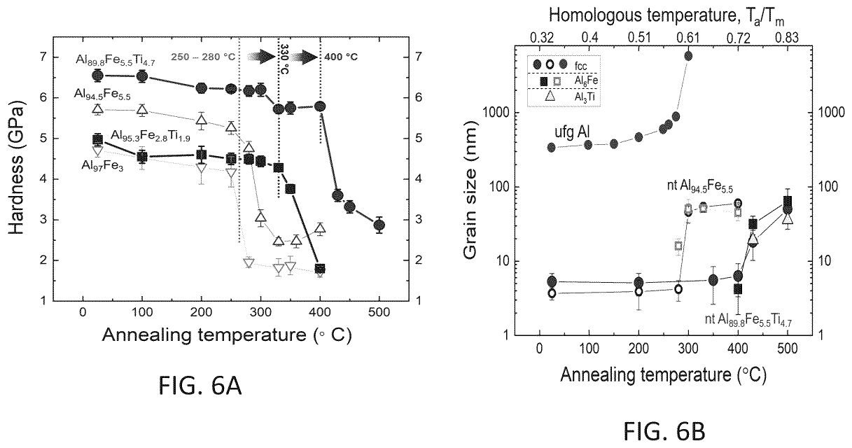

Mechanical response to annealing and elevated temperature: The hardness values of binary and ternary nt Al alloy films are compared in FIG. 6. The as deposited nt Al_{89.8}Fe_{5.5}Ti_{4.7} exhibit an exceptionally high hardness, 6.6±0.2 GPa, and annealing at 400° C. only leads to slight hardness reduction to 5.8±0.1 GPa. Annealing experiments at 430° C. and 500° C. resulted in steep hardness drop to 3.6±0.2 and 2.9±0.2 GPa. In comparison to the ternary alloy, the Al_{94.5}Fe_{5.5} binary alloy retains its hardness of ˜5 GPa up to 280° C. The binary Al₉₇Fe₃ alloy has similar thermal stability up to 280° C. with a hardness of 4 GPa, and the ternary Al_{95.3}Fe_{2.8}Ti₁₉ is stable up to 330° C.

Microscopic studies show that the average grain size for fcc Al, Al₆Fe and Al₃Ti is 50±23, 64±30 and 36±18 nm, respectively, after heat treatment at 500° C. (FIG. 6b). 400° C. marks the onset of recrystallization for Al_{89.8}Fe_{5.5}Ti_{4.7}, and grain coarsening occurs at ˜330° C. for Al_{95.3}Fe_{2.8}Ti_{1.9}, in comparison to coarsening at 250-280° C. for Al₉₇Fe₃, Al_{94.5}Fe_{5.5} and Al_{89.8}Fe_{10.2}. This observation strongly suggests that it is the addition of Ti rather than more Fe that drastically enhances thermal stability.

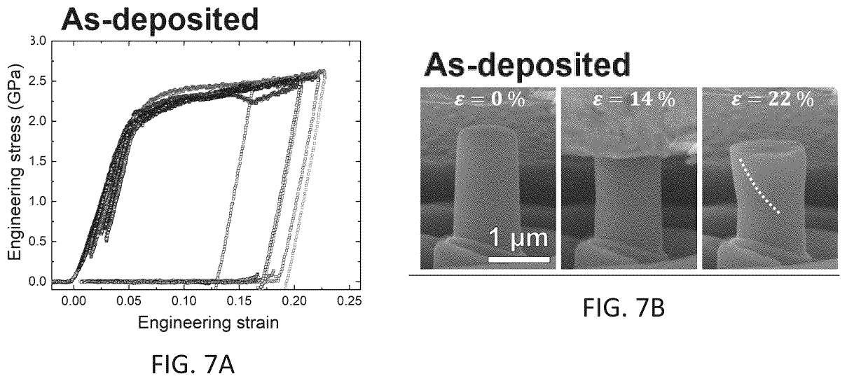

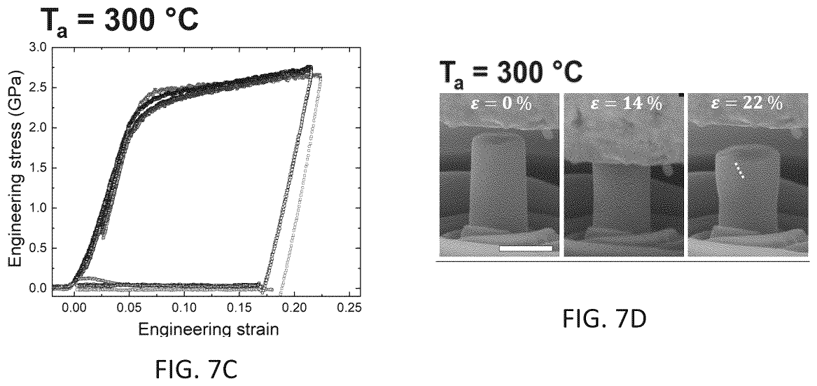

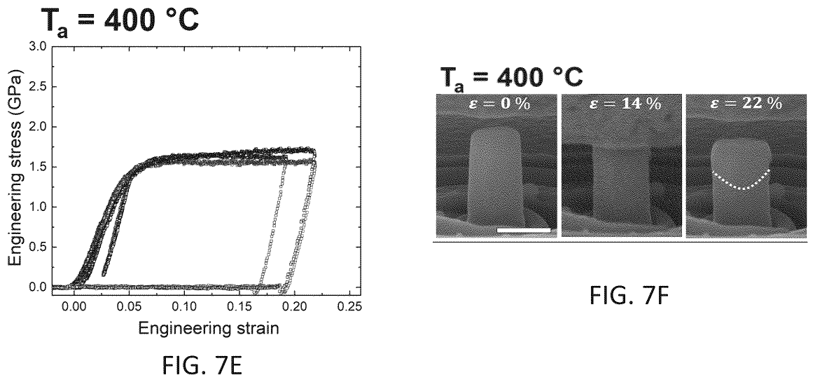

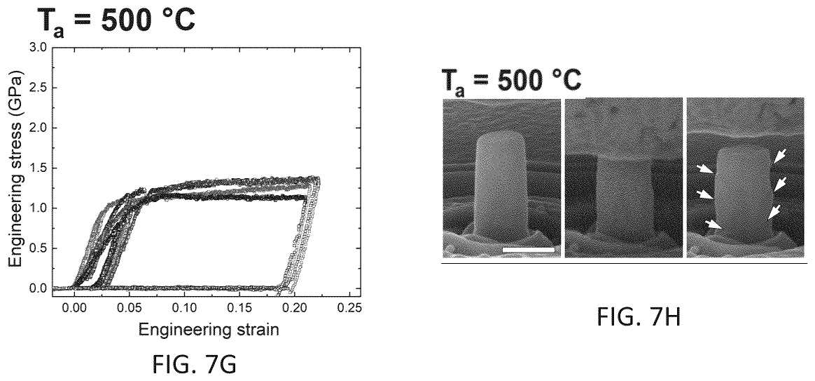

In-situ micropillar compression experiments have been carried out inside a scanning electron microscope, and engineering stress-strain curves of the as-deposited and annealed Al—Fe—Ti alloys tested at room temperature are compared in FIGS. 7A through 7F. Noted that representative engineering stress-strain curves were present due to the different evolutions of instantaneous indenter-pillar contact area upon deformation for each different specimen, and stress at 7% strain was selected to represent flow stress based on the consideration that it safely exceeds yield point but has not proceeded to a strain level where stress is overestimated because of developing geometry (details can be found in methods). The stress-strain curves of all specimens are mostly smooth without serrations. The flow stresses of the as-deposited nt Al—Fe—Ti and specimens annealed at ≤300° C. are similar, ˜2.2-2.3 GPa when ¿=7% (FIGS. 7A and 7C). A preferential dilation took place near the pillar top, manifested as a reverse cone; meanwhile, a shear band was nucleated at a strain of ˜15%, and propagated at higher strain as shown in FIGS. 7B and 7D. A noticeable drop of flow stress to ˜1.6 GPa (8=7%) occurred on specimens annealed at 400° C. (FIG. 7E). No dilation of pillar top was noticed on the specimen annealed at 400° C. and the shear banding became prominent as shown in FIG. 7F. After annealing at 500° C., flow stress decreased to 1.2 GPa, and deformation seemed more homogeneous, and a rough surface developed on the deformed pillars. Referring to FIGS. 7B, 7D, 7F and 7H it is seen that when specimens are annealed at <400° C., micropillars retain high yield stresses (˜2 GPa), and SEM snap shots show preferential dilation near pillar top and few shear bands. After annealing at 400-500° C., the yield strength of specimens decreases to 1.4 and 1 GPa, respectively, and the deformed pillar surface appeared rough as labeled by arrows. Two partial unloading segments were deliberately incorporated mostly in elastic regimes to validate alignment conditions. Tₐ denotes annealing temperature.

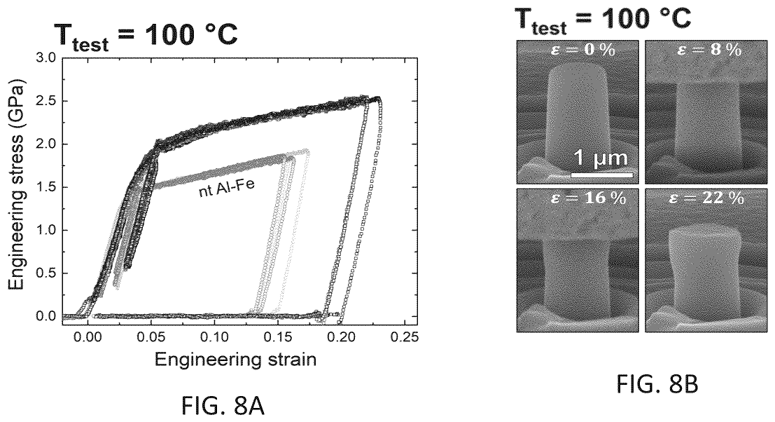

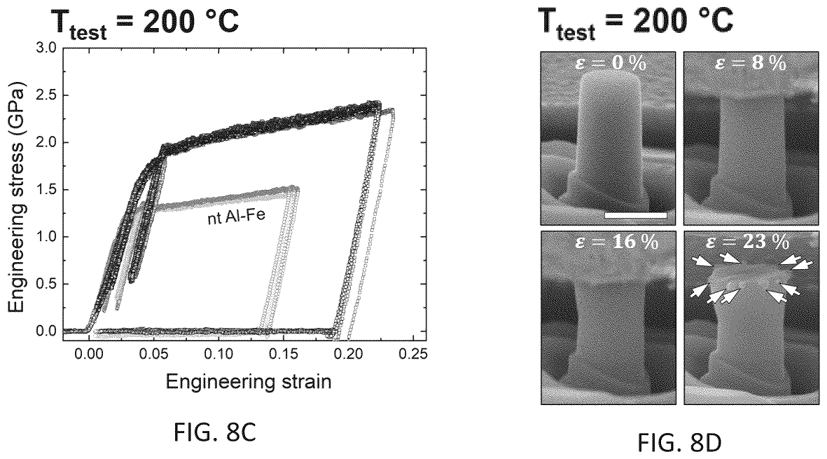

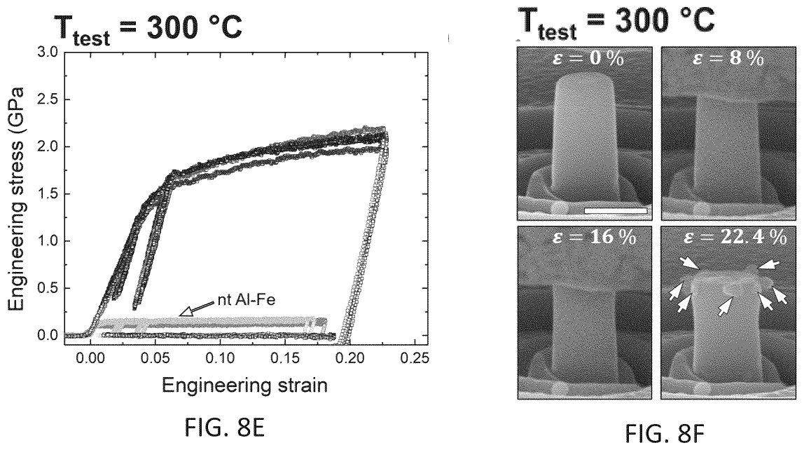

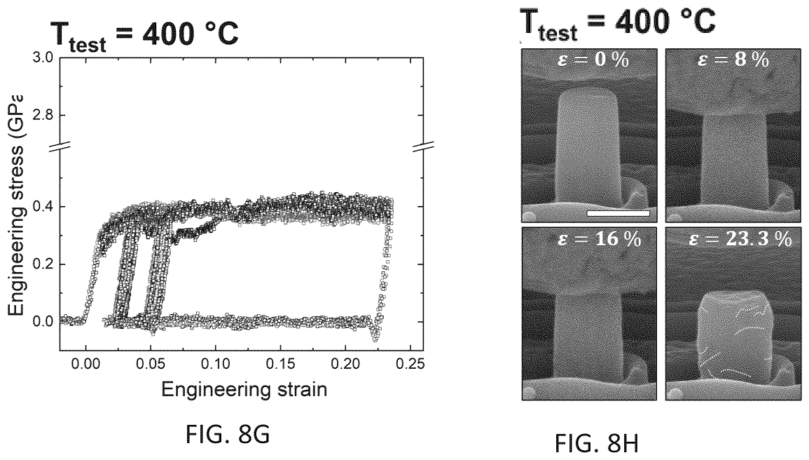

In-situ compression experiments on nt Al—Fe—Ti were conducted at elevated temperature up to 400° C. The flow stress (8=7%) of the Al—Fe—Ti tested at 100, 200 and 300° C. is ˜2, 1.9 and 1.7 GPa, respectively (FIGS. 8A, 8C and 8E). It is noted that ˜77% of flow stress was maintained when tested at 300° C. A precipitous softening to 360±50 MPa occurred when tested at 400° C. Testing at 100° C. also gave rise to a preferential dilation at the upper portion of the micropillars without shear bands up to ˜22% strain (FIG. 8B). Nanoclusters formed on the micropillars tested at 200 and 300° C., as revealed by the SEM snapshots in FIGS. 8D and 8F. High-density surface wrinkles emerged on the surface of pillars tested at 400° C. in FIG. 8H. Referring to FIGS. 8A, 8C, 8E and 8G, it is seen that flow stresses measured at ε=7% are higher than 1.5 GPa while testing temperature is 300° C. or below, and drastically decline to ˜ 0.38 GPa when tested at 400° C. Nanoparticles emerged on the pillar surface after deformation at 200 and 300° C. Engineering stress-strains curves of binary nt Al—Fe tested at elevated temperatures were cited from a literature.

Composition-structure-strength correlations: As-deposited nt Al_{89.8}Fe_{5.5}Ti_{4.7} has a hardness of ˜6.6 GPa as comparing to ˜5.7 GPa of as-deposited Al_{94.5}Fe_{5.5}. Prior study showed that the grain size of sputtered Al—Fe is closely related to Fe concentration. Prior studies on sputtered binary supersaturated Al alloys with dominant fcc phase showed that the slope of hardness increment with increasing Mo, Ni and Fe content is ˜0.28, ˜0.33 and ˜0.68 GPa per atomic percent, respectively. Consequently, and it requires ˜16% of Mo, 8-9% of Ni and only 5-6% of Fe to reach a high hardness of 5 GPa. Moreover, the effectiveness of Fe for microstructure refinement of binary Al alloys was proven to be superior to Ag, Ti, Cr, Mg, Mo and W. For instance, ˜5% of Ti in sputtered nt Al—Ti alloys resulted in an average grain size of ˜180 nm. However, the nt Al—Fe and Al—Fe—Ti with columnar nanograins have an average twin spacing and grain size of ˜23 and ˜5 nm, respectively. Accordingly, we infer that Fe mainly plays the role of an effective grain refiner and Ti, as the third element added to Al—Fe, adds the customized functionality, particularly thermal stability in this case.

Nt Al—Fe—Ti alloys were sputter-deposited from a plasma state with atomization by way of ion bombardment and analytical analysis revealed homogenously dispersed Fe and Ti in Al host. Our prior studies showed that excess doping of Fe would expand the Al lattice in binary Al—Fe despite a smaller atomic radius of Fe (r_{Fe}=0.124 nm vs. r_{Al}=0.143 nm), leading to a linear increment in lattice constant with increasing Fe content when C_{Fe}≥2.5%. Occupation of Fe at interstitial sites and/or formation of nanoclusters in Fe—Fe pairs might account for the lattice expansion. This phenomenon is different from solute segregation to GBs in several nc metals. The addition of 4.7% of Ti (r_{Ti}=0.148 nm) to binary Al—Fe increased the lattice constant further to 0.4067 nm versus 0.4049 nm of monolithic Al and 0.4052 nm of Al_{94.5}Fe_{5.5}. This suggests that Ti in as-deposited form might primarily stay in solid solution and had not driven Fe atoms off the sites taken originally by Fe in binary alloys. Notwithstanding the very limited solubility of Fe and Ti at equilibrium, i.e. 0.03 and 0.28%, respectively, the supersaturated Fe and Ti in the current study far exceed the equilibrium solubilities, benefiting from the high quenching rate, in the range of 10⁶ to 10¹⁰ K/s, during sputtering.

The task of decoupling strengthening contributions from each mechanism is complex considering the possibly invalid dislocation pile-up model at nanoscale, physico-chemical interaction among Fe, Ti and Al-rich environment and so forth. The high strength of nt Al—Fe—Ti can be tentatively estimated: σ_{AlFeTi}=3τ*+Δσ_{Fe,sss}+Δσ_{Fe,ncsp}+Δσ_{Ti,sss}+Δσ_{Ti,ncsp}.

Solid-solution strengthening, σₛₛₛ, arises from the variations of shear modulus and lattice constant from dopants (Fe and Ti). Nanocrystalline solution pinning, σ_{ncsp}, operates in nc alloys wherein the distance for dislocation bowing is affected by grain size, and the shear modulus and lattice constant are accordingly altered by dopants. Due to a fine grain size, ˜5 nm, in ternary Al—Fe—Ti alloys, Hall-Petch strengthening built on full dislocation-mediated plasticity would be replaced by a shift of deformation mechanisms to partial dislocation and/or GB-mediated processes. Diverse computational and empirical studies investigated the transitions among deformation mechanisms in fcc metals, including Cu, Ni and Al. Consequently, we instead used the barrier shear stress, τ*, for single dislocation transmission across GB to predict maximum GB strengthening. In the context of this disclosure fine grains in the size range of 2 nm-100 nm are termed fine grains.

Given Δσ_{Fe,sss}=40-300 MPa; Δσ_{Fe,ncsp}=100-500 MPa; Δσ_{Ti,sss}=7-50 MPa; Δσ_{Ti,ncsp}=30-150 MPa, we arrive that the estimated maximum flow stress, σ_{AlFeTi}, is ˜4 GPa (3τ*=˜3 GPa where a Taylor factor of 3 is applied), comparable to the 2.2-2.3 GPa measured from in-situ studies.

From compressive experiments, comparing to the flow stress of ˜1.6 GPa for Al_{94.5}Fe_{5.5}, the Al_{89.8}Fe_{5.5}Ti_{4.7} has a greater flow stress, ˜2.2 GPa. The maximum calculated contribution of Ti (about 200 MPa) does not match the measured difference in flow stress. It was noted that in-situ compression experiments on Al—Fe—Ti alloys generated not only localized dilation but also shear band. Such a strengthening effect may arise from the modification of energy state and deformation physics at columnar GBs. TEM studies show grain coarsening from detwinning account for the localized expansion of pillar heads in several binary nt Al alloys. Furthermore, the addition of Ti may increases the detwinning resistance for the migration of Shockley partials in ternary alloys, and consequently leads to strengthening of the ternary alloys.

The synergistic effect of Ti and Fe on thermal stability of nt Al—Fe—Ti alloys: Conventional Al alloys often operated at a maximum temperature of 130° C. due to their low strength at elevated temperatures. In comparison, the nt Al—Fe—Ti alloys have superb high temperature thermal stability and retain high hardness even after annealing was performed at 400° C. The superb thermal stability of nt Al—Fe—Ti leads to the retention of high hardness of ˜5.8 GPa after annealing at 400° C., and a high flow stress of ˜1.7 GPa even when tested at 300° C. A prior study shows that nc Al—Fe—Zr has a flow stress of ˜460 MPa when tested at 250° C. EDS (FIG. 3b) and TEM (FIG. 5b) studies show that, at 400° C., Fe segregation occurs, a signal for the onset of phase segregation and softening. It is noted that the occurrence of severe chemical segregations coincides with the structural coarsening, suggesting that the Zener drag from solutes in nt Al—Fe—Ti plays important roles to kinetically suppress grain growth. A uniform dispersion of solutes in supersaturated solid solution alloy is imperative to refine the microstructure of sputtered Al alloys and improve their thermal stability. In a duplex Al—Fe alloy rapidly quenched at ˜10⁶ K/s, containing Al₆Fe phases, a drastic softening occurred at an annealing temperature of 350° C. due to the transformation of Al₆Fe into AlmFe (m<6) and rapid grain growth resulting from further deprivation of Fe from lattice and GBs. The solution to improve thermal stability of Al—Fe alloys often involved the usage of a third element to improve Zener pinning effect either through a different type of nanoprecipitate, such as Al₃Zr in nc Al—Fe—Zr, or through compositionally enhanced nanoprecipitation, such as the formation of Al₁₀Fe₂Ce phase in an Alcoa CU78 alloy. It is known that formation of nanoprecipitates regularly hardened commercial Al alloys through Orowan looping and/or dislocation shearing, but hardness increment from nanoprecipitation in nt Al—Fe—Ti is overshadowed by softening deriving from collapse of nt structure. The mechanism for the thermal stability of Al—Fe—Ti solid solution alloys is clearly different. At the basis of rigorous investigations through this study, it is worth mentioning that the mechanical stability of Al—Fe—Ti solid solution alloys in response to high temperature treatment results from composition-dependent structural stability, different from the hardening gained through GB energy relaxation and severe Mo segregation of electrodeposited nc Ni—Mo alloys upon annealing.

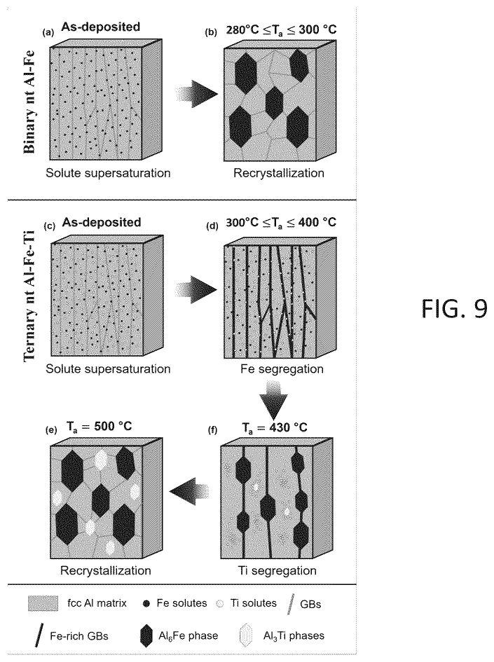

FIG. 9 shows schematic representations of microstructures showing that both nt binary and ternary Al alloys prevailing upon heat treatment and illustrating superb thermal stability of nt Al—Fe—Ti alloys. Sections marked a and b show that binary Al—Fe with solute supersaturation and columnar nanograins coarsens as 280° C.≤Tₐ≤300° C. upon Al₆Fe formation. Sections marked c and d show that, in comparison with Al—Fe, Fe segregation at GBs as a consequence of Ti solute pinning and lowered GB energy occurs at 300° C.≤Tₐ≤400° C.; Sections marked e and f show that the Al₆Fe swiftly flourishes the moment that Ti starts to segregate (Tₐ=430° C.) and eventually ternary alloys fully recrystallize (Tₐ=500° C.) . . . . The recrystallization temperatures of 400-430° C. for nt Al—Fe—Ti alloys are much higher than 250-280° C. for nt Al—Fe. The AlFe formation temperature in nt Al—Fe is in general in agreement with prior studies reporting the decomposition of supersaturated Al—Fe alloys prepared via mechanical alloying and rapid solidification process. The recrystallization of binary Al—Fe alloys is often accompanied by the formation of metastable Al₆Fe phase, presumably due to the inadequate Fe left in solid solution to prevent grain coarsening as illustrated in sections a and b of FIG. 9. In comparison to the binary Al—Fe alloys, there is insignificant precipitation of Al₆Fe when annealing temperature≤400° C. in the ternary Al—Fe—Ti alloys. In what follows, we attempt to interpret the role of Ti solutes on the formation of Al₆Fe and grain coarsening in the ternary Al—Fe—Ti alloys.

First, Ti solutes kinetically inhibit the formation and growth of Al₆Fe presumably due to a high decomposition temperature of Ti supersaturation in Al. It has been long established that the logarithm of the solubility of diverse solutes in solid Al is linearly proportional to the absolute operation temperature. Specifically, log (CFe in at. %) in Al pronouncedly declines from ˜0.012 to ˜0.004 as temperature drops from 700 to 600° C., whereas the reduction ratio in solubility of Ti, log(C_{Ti}) from ˜0.157 at 700° C. to ˜0.145 at 500° C. is comparably insignificant, and consequently supersaturated Al—Fe decomposes more readily at lower temperature than supersaturated Al—Ti does. Interestingly, despite the general agreement on Al₆Fe formation in Al—Fe alloys at 280-330° C. with prior studies, the formation temperature for Al₃Ti is under debate. Various cast and rapidly solidified Al—Ti alloys exhibited no appearance of L1₂ or D0₂₂ Al₃Ti phase even up to 600° C., for which the discrepancy in liquid and solute solubilities of Ti in Al solvent might account. In general, the low liquid solubility of Ti leaves limited amount of solutes in solid Al, making the kinetics of Al₃Ti formation sluggish during quenching, but Al—Ti fabricated via melt-spinning and mechanical alloying with relatively high Ti solute content exhibited formation of Al₃Ti at temperature with a widespread range from 300 to 500° C. In this study, the presence of Ti postponed the Al₆Fe formation from ˜280° C. in binary nt Al—Fe to 400-430° C. in ternary nt Al—Fe—Ti. The comparison of STEM-EDS and phase analyses at 430° C. in FIGS. 2C and 3C revealed that fully crystallized Al₆Fe had formed, whereas Al₃Ti has not been largely detected and a majority of Ti solutes tends to agglomerate but remains inside fcc lattice. Upon recrystallization, the temperature overshoot resulted in sub-micron large Al₆Fe agglomerations with sub-nanograins with random orientations, whereas Al₃Ti retained intact and smaller nanograins (FIGS. 3D and 4D). The improvement on thermal stability of ternary nt Al alloys due to the presence of Ti is illustrated in FIGS. 9C-9F.

Second, the Fe segregation at GBs may stabilize the nanograins nt Al—Fe—Ti (up to 400° C.). A Fe segregation at GBs was captured in FIGS. 3B and 5B. It unveils a gradual decline in lattice constant upon annealing from 250 to 400° C. Before annealing, the Fe solutes occupying interstitial sites expand Al crystal lattice. The declination of lattice parameters during annealing thus indicates the exit of Fe from interstitial sites to probably GBs before recrystallization. The decrease of lattice constant below the value of pure Al is attributed to the substitutional Fe solutes with smaller atomic radius than Al. There has been increasing evidence showing that GB segregation could thermodynamically stabilize nc alloys with selective compositions against grain growth. Thermodynamically, the driving force for GB migration can be reduced or eliminated when certain types of solute segregate to the GBs. The GB stability depends on the competition between the solute segregation energy, GB energy and the energy deficit because of the formation of intermetallic phase. The empirical observation of Al Fe formation at a moderate homologous temperature in binary Al—Fe and the quantum mechanical calculations suggest that Al—Fe is a metastable system. It is interesting to note that the presence of Ti enabled a Fe segregation at GBs and stabilize nanograins in Al—Fe—Ti up to 400° C. We speculate that the release of interstitial Fe solutes may reduce elastic strain energy and the GB segregation could lower GB free energy. The disparity of heat of mixing between Al—Fe (−11 KJ/mol) and Al—Ti (−30 KJ/mol) could lead to the repulsive force between Ti and Fe in Al-rich environment and facilitate Fe segregation at GBs.

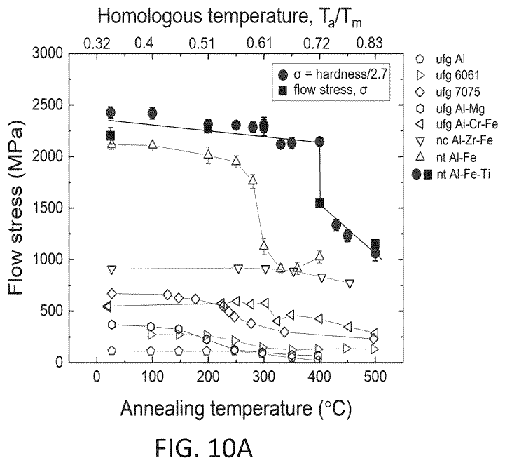

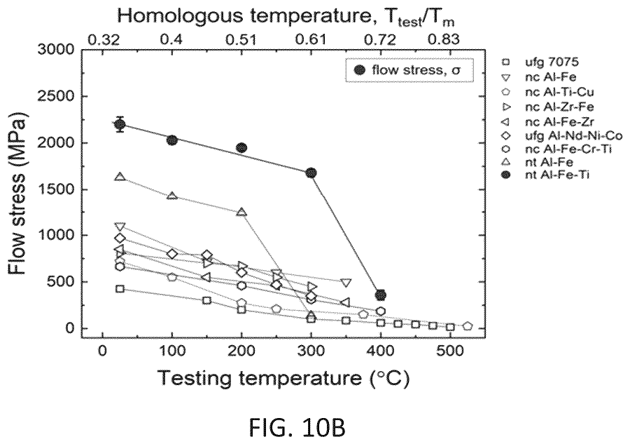

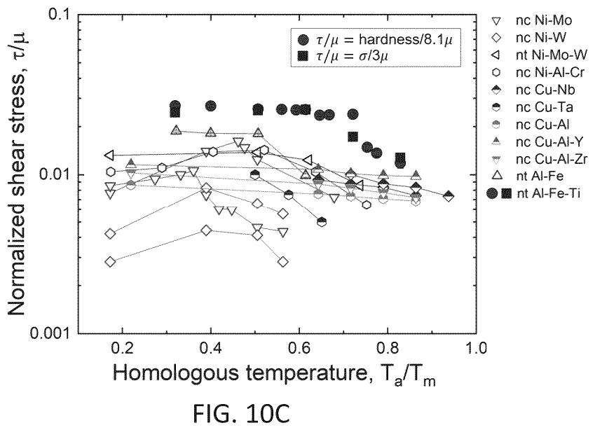

Superb structural and mechanical stability upon heat and at elevated temperatures: FIG. 10 shows comparison of thermal stability and mechanical behaviors at elevated temperatures of nt Al—Fe—Ti alloys with data collected from literature FIG. 10A compares the thermal stability of nt Al—Fe—Ti alloys with various representative ufg, nc and nt Al alloys. The flow stress translated from hardness measurements and from compressive experiments are measured at room temperature on annealed alloys. The nt Al—Fe—Ti has an exceptionally high flow stress (>2 GPa) up to an annealing temperature of 400° C., making it one of the strongest Al alloys, ever reported with remarkable thermal stability. The structural stability for nt Al—Fe—Ti is the primary reason for the retention of exceptional mechanical behaviors, unlike the mechanical gain from nanoprecipitation in nc alloys, such as nc Al—Zr—Fe. These ufg Al alloys underwent grain growth at the range of 100 to 230° C. mostly because of the GBs with excess mechanical energy. The mechanical behaviors at high service temperatures are critical. FIG. 10B compares the flow stress as a function of testing temperature for our nt Al—Fe—Ti and various ufg and nc Al alloys, especially the ones constructed with multiple transition metals. The flow stress of nt Al—Fe—Ti could be maintained at ˜1.7 GPa at a test temperature of 300° C., making it one of the strongest Al alloys for high temperature applications. In the plot of normalized shear stress, t/u, as a function of homologous annealing temperature (Tₐ/Tₘ), the nt Al—Fe—Ti has significant advantages comparing to nc, nt Cu and Ni alloys. Many of previously reported nc and nt Ni alloys could reach high strength but are prone to softening at a relatively low homologous annealing temperature due to grain coarsening. Nt Al—Fe—Ti alloys in this study overcome some inherent weakness of Al alloys and can be potentially applied for moderate temperature applications. FIG. 10C shows the normalized shear stress (t/u) as a function of homologous temperature (Tₐ/Tₘ) for nt Al—Fe—Ti in comparison with other fcc-based (Ni— and Cu—) nc and nt alloys. Tₜₑₛₜ and Tₘ denotes testing and melting temperature, respectively. From FIG. 10C, it can be seen that the nt Al—Fe—Ti alloys can reach high strength and retain outstanding structural stability at a relatively high homologous temperature, in contrast to previously reported nc and nt Cu and Ni alloys, suggesting that selectively coupled solute effect be promising for further enhancing mechanical behaviors of various NC alloys at elevated temperatures.

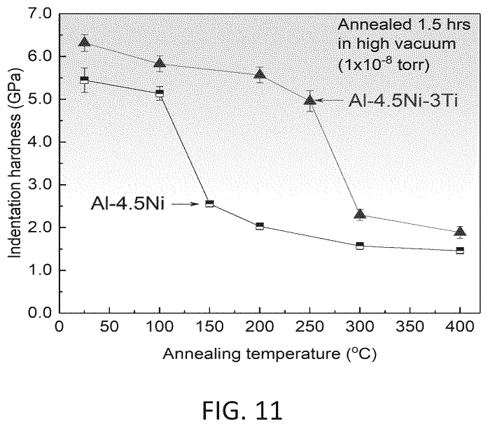

From the above discussion, it is clear that the combination of Fe and Ti rendered a better thermal and mechanical behaviors though addition of Ti into other high-strength binary Al alloys and could improve thermal stability to some extent. An example of ternary of Al—Ni—Ti is given in FIG. 11 showing the hardness evolution of Al-4.5Ni and Al-4.5Ni-3Ti at different annealing temperatures ranging from 100 to 400° C. As shown in FIG. 11, the hardness of Al-4.5 Ni plummets in the annealing temperature range of Tₐ=100-150° C. and reaches a plateau of ˜2 GPa after 300° C. But the addition of three atomic percent Ti can postpone the softening point of Al-4.5 Ni to 250-300° C.

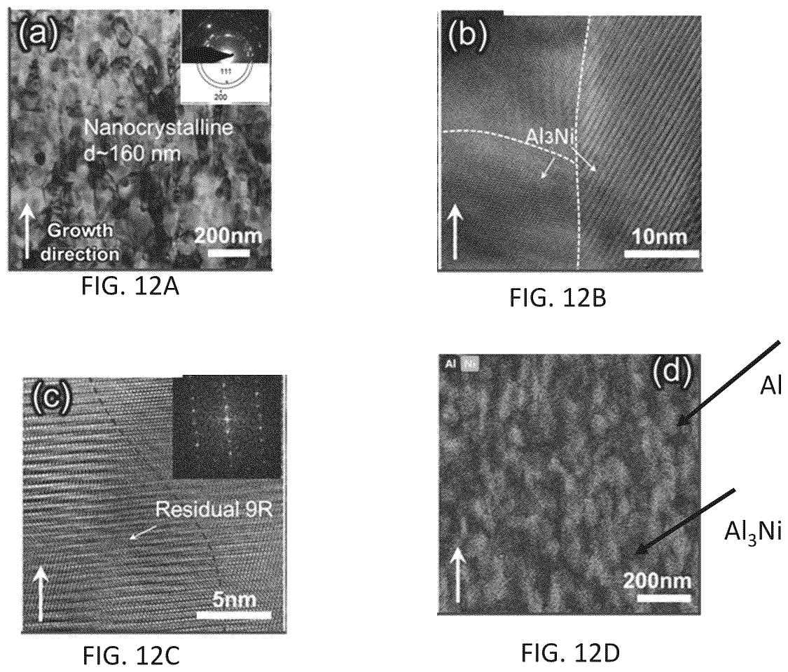

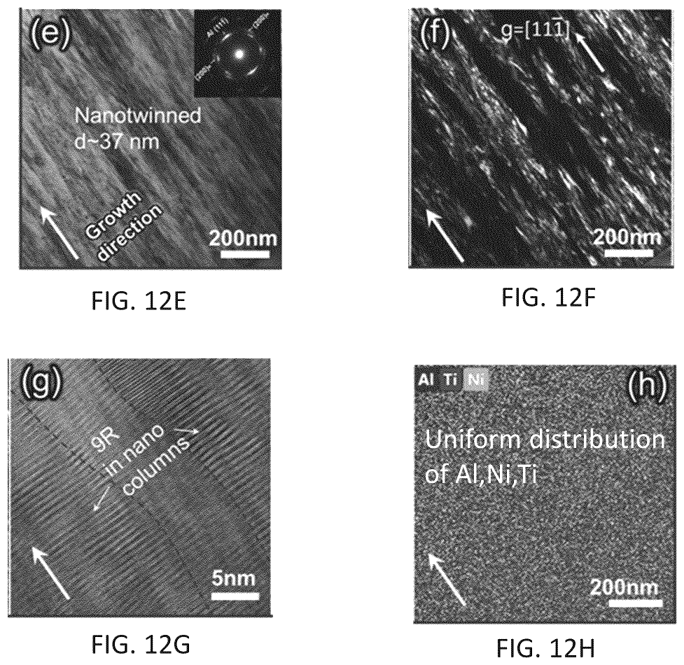

FIGA. 12A through 12H show the comparisons of microstructure and chemistry of annealed Al—Ni and Al—Ni—Ti alloy It is noticed that the hardness of ternary alloy can remain as high as 5 GPa after 1.5 hours annealing at 250° C. TEM analyses (FIGS. 12A through 12H) on annealed Al-4.5Ni and Al-4.5Ni-3Ti show that the recrystallization temperature has been increased from 150° C. to 300° C. due to the addition of Ti solute. Recrystallization led to nanograins with an average grain size of 160 nm (shown in FIG. 12A) in Al-4.5Ni annealed at 150° C. The A₁₃Ni (shown in FIG. 12B) and a small number of residual 9R phases (shown in FIG. 12C) are observed among recrystallized grains in Al. As expected, Ni segregation (shown in FIG. 12D) occurred in annealed Al-4.5Ni. On the contrary, Al-4.5Ni-3Ti annealed at 250° C. still have nanotwinned columns with an average grain size of ˜37 nm (as shown in FIGS. 12E through 12F). High-density 9R phases still exist in nano columns without intermetallic (as shown in FIG. 12G). Moreover, EDS map shown in FIG. 12H shows uniformly distributed Ti and Ni solutes in annealed Al-4.5Ni-3Ti.

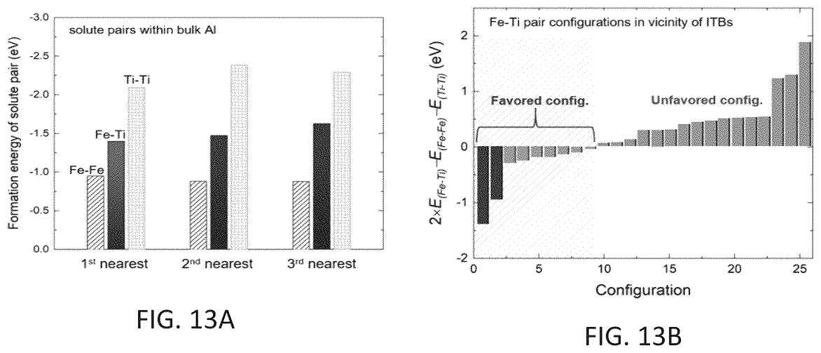

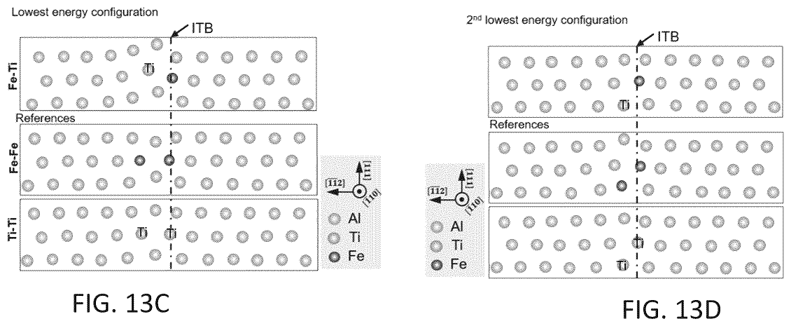

Density function theory (DFT) calculations were utilized to prove that Ti solutes kinetically and energetically inhibit the formation and growth of Al₆Fe. DFT was applied to compare the formation energies of Fe—Ti pairs to Fe—Fe and Ti—Ti pairs in Al lattice (Ti atoms occupy substitutional sites differently distant from Fe substitutional reference site). FIGS. 13A through 13D show density functional theory (DFT) calculations to compute the formation energies of substitutional solute pairs in Al solvent and optimal solute configurations in vicinity of ITBs Fe—Ti pairs located at the first, second and third nearest neighbor sites have the respective formation energies of −1.399, −1.472 and −1.626 eV, comparing to −0.948, −0.88 and −0.878 eV for Fe—Fe pairs, suggesting that the Fe—Ti solute combination in Al host is thermodynamically preferred (see FIG. 13A). To expel Fe solutes from solid solution to form Al₆Fe, a higher energy penalty is imposed in the presence of adjacent Ti atoms. Second, the Fe segregation at ITBs in the presence of Ti leads to improved thermal stability up to 400° C. The energy of solute pairs in vicinity of ITB was also computed using DFT. As shown in FIG. 13B, the comparable energies of Fe—Ti pairs, expressed as 2×E_{Fe—Ti}−E_{Fe—Fe}−E_{Ti—Ti}, around ITBs suggest 9 energetically favored atomic configurations out of 25. The lowest and second lowest energy configurations are illustrated in FIGS. 13C and 13D, manifesting that positioning Fe solutes at the core sites of ITBs with adjacent Ti solutes produces the most energetically favorable (stable) configurations. The DFT calculations support our empirical observations that superb thermal stability of NT Al—Fe—Ti is related to the Fe segregation along ITBs at 400° C.

Based on the above description, it is clear that ultrahigh-strength and thermally stable nanostructured Al alloys can be constructed by incorporating both a grain refinement element Fe, and a stabilization agent, Ti. The Al—Fe—Ti solid solution alloys exhibit superb microstructural stability up to 400° C., 0.72 Tₘ of Al. In-situ micropillar compression experiments show that the Al—Fe—Ti alloys can preserve an exceptionally high flow stress of ˜1.7 GPa when tested at 300° C., making these one of the strongest high temperature Al alloys reported to date. Ti inhibits the formation of metastable Al₆Fe intermetallic and Fe segregate to the grain boundaries, leading to the superb thermal stability of nanostructures. This disclosure demonstrates the synergistic usage of solutes for the design of ultra-strong and thermally stable nanostructured Al alloys for harsh environments. The coatings could either be deposited on the substrates by using a bulk alloy source with a fixed composition, or by different pure sources of the constituents of an aluminum alloy. When a single alloy source is used as the source for deposition, the result will be an alloy coating with nearly the same composition as the single alloy source The power has insignificant effect, if any on the composition of the coatings and mainly influences the deposition rate. Different sources of each constituent of the coating would help tailor the composition of the coatings. If a single alloy source is used, the coating could only have a fixed composition.

It should be recognized that in the deposition method of sputtering, the sputter yield value for each constituent metal depends both on the source material and deposition parameters which include the atomic mass of the metal, the power through which the ion is accelerated and deposition chamber atmosphere. The deposition rate from each source for each constituent of the aluminum alloy is approximately linearly proportional to the applied power. In some of the experiments leading to this disclosure, a power of 200 watts was employed for deposition of Al, Fe and Ti separately on a substrate to measure the deposition rate for each source. After knowing the deposition rate, then, power is needed for each source to reach required compositions for the aluminum coatings was calculated. In our experiments of preparing Al_{89.8}Fe_{5.5}Ti_{4.7} alloy coatings, a power of 300 watts was used to deposit Al; 58 watts for Ti and 42 watts for Fe. The sputtering technique ensures the objects that leave the target or the source and deposit onto substrate are in atom or small atom cluster forms and therefore the constituent would fully dissolve into the coatings on the substrate. The coating after deposition has single face-centered cubic (fcc) phase.

It should be recognized that for the deposition of the coatings from different sources for each constituent of the coating, there can be one or more than one source for a single constituent. Thus we have multiple approaches: a single source of each of the constituents; one or more sources for each o the constituents; a single alloy source for the coating. A source for a single constituent can be essentially pure metal of chemical grade purity or an alloy containing the desired constituent of the coating. It should be recognized that it is possible to have multiple sources some of which may be elements and some of which may be alloys. In all combinations, it is possible to have more than one source for a single constituent of the coating.

Based on the above detailed description, it is an objective of this disclosure to describe a high-strength aluminum alloy coating on a metal or an alloy, containing an aluminum matrix, 9R phase, fine grains, nanotwins, and at least one solute in the aluminum capable of stabilizing grains of the aluminum matrix. As mentioned earlier, in the context of this disclosure, grains in the size range of 2 nm-100 nm are termed fine grains. Thus, fine grain size could range from 2 nm to 100 nm. Examples of solute suitable for the high-strength coating of this disclosure include, but not limited to iron, titanium, zirconium, and chromium. In some embodiments of the high-strength coating of this disclosure, there can be more than one solute. In some embodiments of this coating, there can be two solutes. A non-limiting example of the two solutes are iron and titanium. In some embodiments of the high-strength aluminum alloy coating of this disclosure, the compressive strength of the coating is in the range of 1.5-2.5 Gpa in the temperature range 25 C-400 C.

In some embodiments of the above described high-strength aluminum alloy coating the fine grains are equiaxed (depending on method) or columnar. In some embodiments of the high-strength aluminum alloy coating of this disclosure, the coating has thickness in the range of 0.1-200 micrometers. In some embodiments of the high-strength aluminum alloy coating of this disclosure, the fine grains are in the size range of 2 nm-10 nm. In some embodiments of the high-strength aluminum alloy coating of this disclosure, inter-twin spacing of the nanotwins is in the range of 5 nm-30 nm. In some embodiments of the high-strength aluminum alloy coating of this disclosure, wherein the two solutes are iron and titanium, the iron content is in the range of 2-10 atomic percent and the titanium content is in the range of 2-10 atomic percent. In some embodiments of the high-strength aluminum alloy coating of this disclosure, the high-strength aluminum coating has deformability in the range of 5-25%. In some embodiments of the high-strength aluminum alloy coating of this disclosure the hardness of the coating is in the range of 4.5-7.0 GPa.

It is another objective of this disclosure, to describe a method of making a high-strength aluminum alloy coating on a substrate. The method contains the steps of providing a substrate, providing at least one source for each constituent of an aluminum alloy, and depositing atoms of the each constituent of the aluminum alloy from the corresponding at least one source of each constituent of the aluminum alloy on the substrate utilizing a deposition method, wherein the deposited atoms form an aluminum alloy coating containing 9R phase, fine grains, and nanotwins. In some embodiments of the method of this disclosure, the constituents of the aluminum alloy include iron, titanium, chromium and zirconium. In some embodiments of the method of this disclosure, the deposition method can be, but not limited to, one of the following: sputtering, evaporation, laser ablation, and physical vapor deposition. Examples of a substrate suitable for the method of this disclosure include, but not limited to, a metallic material or a polymer material or a semiconductor material. Examples of substrates suitable for the method of this disclosure include but not limited to, silicon, germanium, and gallium arsenide. In some embodiments of the method, the substrate is a metal or an alloy. Examples of metals and/or alloys suitable as a substrate of method include, but not limited to, copper, nickel, and stainless steel, an aluminum alloy, a copper alloy a nickel alloy and a titanium alloy. In some embodiments of the method, where the substrate is an aluminum alloy, the aluminum alloy can contain one or more of the following elements: iron, cobalt, titanium, magnesium, and chromium.

While the present disclosure has been described with reference to certain embodiments, it will be apparent to those of ordinary skill in the art that other embodiments and implementations are possible that are within the scope of the present disclosure without departing from the spirit and scope of the present disclosure. Thus, the implementations should not be limited to the particular limitations described. Other implementations may be possible. Accordingly, it should be understood that the disclosure is not limited to any embodiment described herein. It should also be understood that the phraseology and terminology employed above are for the purpose of describing the disclosed embodiments, and do not necessarily serve as limitations to the scope of the disclosure. Thus, this disclosure is limited only by the following claims.

1. A method of making a high-strength aluminum alloy coating on a substrate, the method comprising:
providing a substrate;
providing at least one source for each constituent of an aluminum alloy;
depositing atoms of each constituent of the aluminum alloy from the corresponding at least one source of each constituent of the aluminum alloy on the substrate utilizing a deposition method, wherein the deposited atoms form an aluminum alloy coating containing 9R phase, fine grains, nanotwins, and at least one solute in the aluminum matrix capable of stabilizing grains of the aluminum matrix, wherein the at least one solute acts to retain a microstructure of coating comprising 9R phase, grains in the size range of 2-100 nm and nanotwins in the temperature range of 25-400 0C, and wherein the at least one solute is in a supersaturated state exceeding its equilibrium solubility.

2. The method of claim 1, where in the constituents of the aluminum alloy include iron, titanium, chromium, and zirconium.

3. The method of claim 1, wherein the deposition method is one of sputtering, evaporation, laser ablation, and physical vapor deposition.

4. The method of claim 1, wherein the substrate is one of a metallic material or a polymer material or a semiconductor material.

5. The method of claim 1, wherein the substrate is one of silicon, germanium, and gallium arsenide.

6. The method of claim 1, wherein the substrate is a metal or an alloy.

7. The method of claim 6, wherein the metal is one of copper, nickel, and stainless steel.

8. The method of claim 6, wherein the alloy is one of an aluminum alloy, a copper alloy a nickel alloy and a titanium alloy.

9. The method of claim 1, wherein the aluminum alloy comprises one or more of iron, cobalt, titanium, magnesium, and chromium.

10. The method of claim 1, further comprising the step of annealing at a temperature to result in an equiaxed grain structure for the coating.

11. The method of claim 10, wherein the annealing temperature is in the range of 430° C.-700° C.
